(19) United States
(12) Patent Application Publication
(10) Pub. No.: US 2025/0220816 A1
(43) Pub. Date: Jul. 3, 2025

(54) CIRCUIT BOARD ASSEMBLY AND TERMINAL DEVICE

(71) Applicant: TRIPLE WIN TECHNOLOGY(SHENZHEN) CO.LTD., Shenzhen (CN)

(72) Inventor: MING-HSUN LEE, New Taipei (TW)

(21) Appl. No.: 18/591,194

(22) Filed: Feb. 29, 2024

(30) Foreign Application Priority Data
Dec. 27, 2023 (CN) 202323598353.X

(51) Int. Cl. H05K 1/11; H01R 12/52

(52) U.S. Cl. CPC H05K 1/117; H01R 12/52; H05K 2201/041; H05K 2201/09181

(57) ABSTRACT

A circuit board assembly includes a first substrate and at least one first pad. The first substrate includes a first surface, a second surface, and a side surface. The first surface and the second surface are opposite to each other along a first direction, the side surface connects the first surface to the second surface, a groove is defined on the side surface and extending through the first surface and the second surface. Each first pad is accommodated in a corresponding groove of the groove and connects to a groove wall of the groove, each first pad includes a first welding surface, a second welding surface, and a third welding surface, the first welding surface connects the first surface, the second welding surface connects the second surface, the third welding surface connects the first welding surface to the second welding surface. The present disclosure further provides a terminal device.

### FIELD

The subject matter herein generally relates to circuit boards, and more particularly, to a circuit board assembly and a terminal device.

### BACKGROUND

Terminal devices may include circuit boards. The circuit board may include a pad on a surface thereof. The pad can connect the circuit board to an electronic component. However, the size of the pad may be limited, which may reduce the strength of the connection between the pad and the electronic component. Therefore, there is a room for improvement in the art.

### BRIEF DESCRIPTION OF THE DRAWINGS

Implementations of the present technology will now be described, by way of example only, with reference to the attached figures.

FIG. 1 is a diagrammatic view of an embodiment of a terminal device according to the present disclosure.

FIG. 2 is an exploded view of the terminal device shown in FIG. 1.

FIG. 3 is an exploded view of the terminal device of another embodiment of a terminal device according to the present disclosure.

FIG. 4 is an exploded view of the terminal device of yet another embodiment of a terminal device according to the present disclosure.

FIG. 5 is atop plan view of a circuit board assembly of the terminal device shown in FIG. 2.

FIG. 6 is a partially enlarged view of an area a circuit board assembly shown in FIG. 3.

FIG. 7 is a top plan view of another embodiment of a circuit board assembly according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

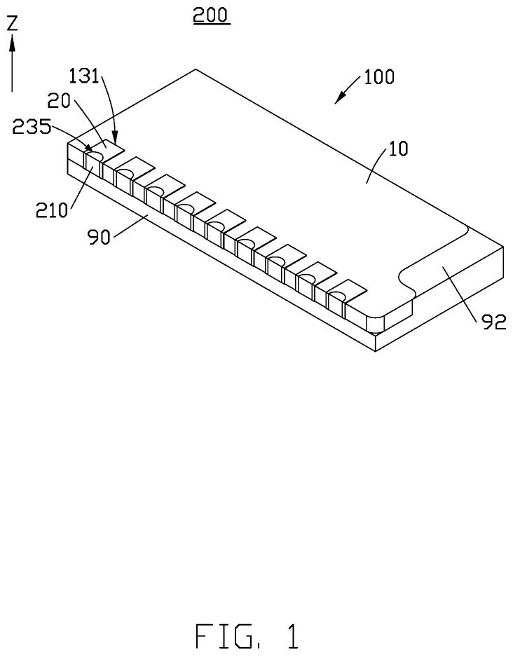

Referring to FIG. 1, a terminal device 200 is provided according to an embodiment of the present disclosure. The terminal device 200 includes a circuit board assembly 100, an external circuit board 90, and at least one second pad 210. The second pad 210 electrically connects the circuit board assembly 100 to the external circuit board 90. The terminal device 200 can be, but is not limited to, an electronic terminal such as a mobile phone, a tablet computer, a camera, a drone, or the like. The circuit board assembly 100 can be used as a connector for connecting to a terminal 91 of the external circuit board 90.

The circuit board assembly 100 includes a first substrate 10 and at least one first pad 20. The first substrate 10 includes a circuit area (not shown), and the first pad 20 is connected to the first substrate 10 and electrically connected to the circuit area. The first pad 20 can connect to the terminal 91 of the external circuit board 90, thereby electrically connecting the first substrate 10 to the external circuit board 90.

In the embodiments, the circuit board assembly 100 includes a plurality of pads 20, the external circuit board 90 includes a plurality of terminals 91, and each first pad 20 connects to one terminal 91.

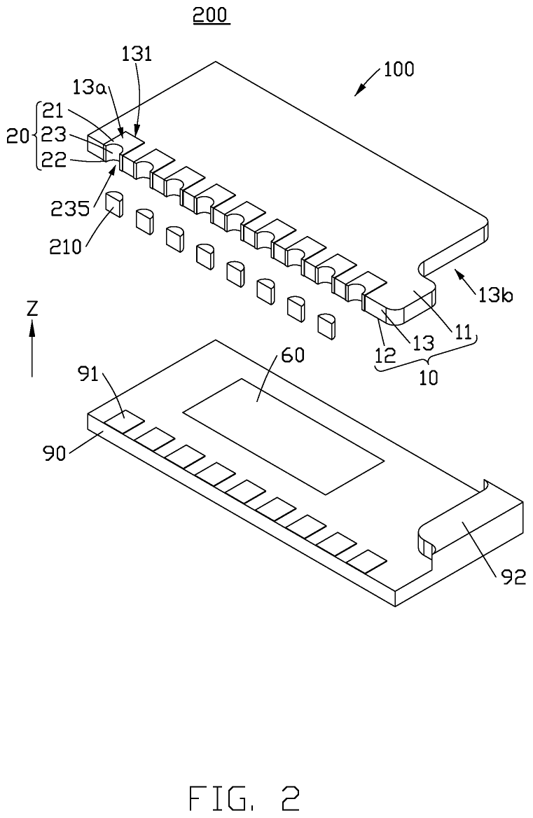

Referring to FIGS. 1 and 2, the first substrate 10 includes a first surface 11, a second surface 12, and a side surface 13. The first surface 11 and the second surface 12 are opposite to each other along a first direction Z, and the side surface 13 connects the first surface 11 to the second surface 12. The first direction Z is a thickness direction of the first substrate 10.

At least one groove 13a is defined on the side surface 13. One end of the groove 13a extends through the first surface 11, and another end of the groove 13a extends through the second surface 12. A groove wall 131 of the groove 13a connects the first surface 11 to the second surface 12.

Each first pad 20 is accommodated in one groove 13a and connects to the groove wall 131. The first pad 20 includes a first welding surface 21, a second welding surface 22, and a third welding surface 23. The first welding surface 21 connects to and may be coplanar with the first surface 11. The second welding surface 22 connects to and may be coplanar with the second surface 12. Each of the first welding surface 21 and the second welding surface 22 may be a flat surface. One end of the third welding surface 23 connects to the first welding surface 21, and another end of the third welding surface 23 connects to the second welding surface 22. In some embodiments, the first pad 20 is made of copper. The first pad 20 is formed by plating copper. In other embodiments, the first pad 20 can be made of other conductive metals.

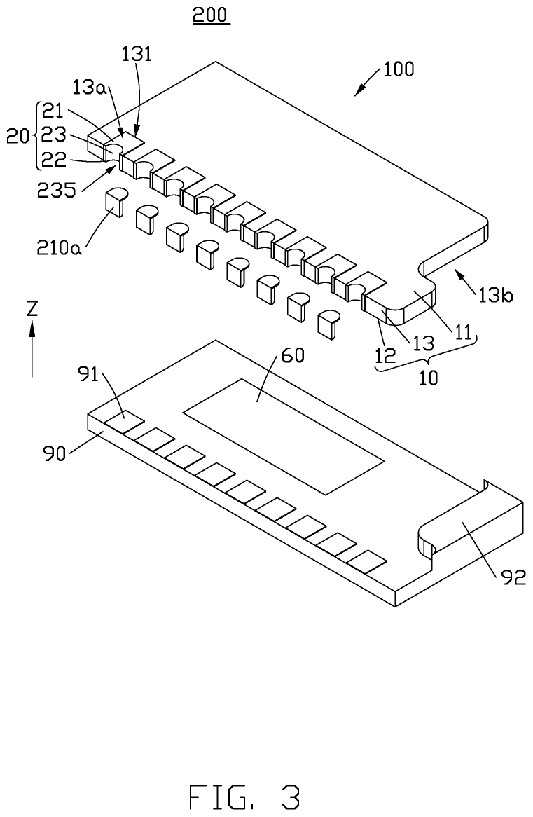

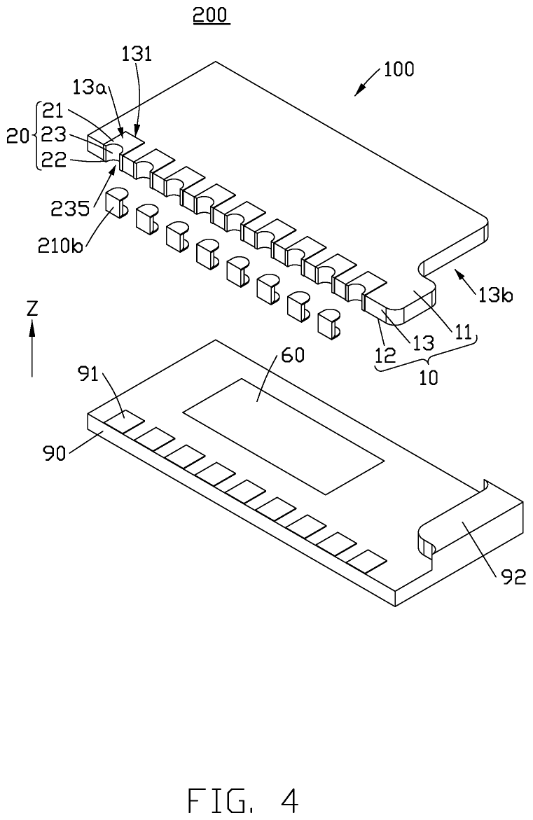

The second pad 210 can connect at least one of the first welding surface 21, the second welding surface 22, and the third welding surface 23 to the terminal 91, to achieve electrical connection between the circuit board assembly 100 and the external circuit board 90. Thus, a welding area of the first pad 20 can be increased, which can facilitate connection of the first pad 20 to the terminal 91, thereby improving a reliability of the connection of the circuit board assembly 100 and the external circuit board 90. Referring to FIGS. 1 and 2, in the embodiment, the second pad 210 connects the third welding surface 23 and the terminal 91. Referring to FIG. 3, in another embodiment, the second pad 210a connects the third welding surface 23 and the terminal 91, and the second pad 210a further extends to the first welding surface 21 and connects to first welding surface 21, which further increases the welding area of the second pad 210a with the first pad 20. Referring to FIG. 4, in yet another embodiment, the second pad 210b further extends toward a gap between the second welding surface 22 and the terminal 91 to further increase the reliability of connection between the circuit board assembly 100 and the external circuit board 90.

A receiving groove 235 is defined on a surface of the first pad 20 away from the first substrate 10. In a welding process, the external circuit board 90 and the first substrate 10 are first stacked along the first direction Z, with the first surface 11 or the second surface 12 facing the external circuit board 90. At least a portion of the terminal 91 is exposed from the receiving groove 235. Then, a solder is filled into the receiving groove 235 and melted by laser heating. The melted solder connects to the terminal 91, the first welding surface 21, the second welding surface 22, and the third welding surface 23. After the solder cools and solidifies to form the second pad 210, the second pad 210 connects the terminal 91 to the first welding surface 21, the second welding surface 22, and the third welding surface 23.

In some embodiments, the solder can be pre-positioned on the terminal 91, and the melted solder flows into the receiving groove 235 during soldering, and the solidified second pad 210 connects the terminal 91 to the first welding surface 21, the second welding surface 22, and the third welding surface 23.

In the circuit board assembly 100 provided in the embodiment of the present disclosure, the first welding surface 21 connects to the first surface 11, the second welding surface 22 connects to the second surface 12, and the third welding surface 23 connects the first welding surface 21 to the second welding surface 22. At least one of the first welding surface 21, the second welding surface 22, and the third welding surface 23 can be used to connect to the terminal 91 through the second pad 210. Thus, a welding area of the first pad 20 can be increased, which can facilitate connection of the first pad 20 to the terminal 91, thereby improving a reliability of the connection of the circuit board assembly 100 and the external circuit board 90.

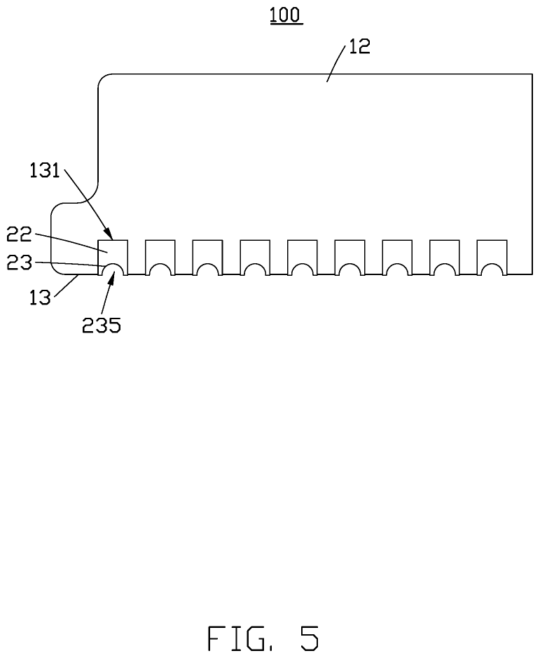

Referring to FIG. 5, in some embodiments, when viewed along the first direction Z, the groove wall 131 is rectangular, and the third welding surface 23 is attached to the groove wall 131 to facilitate increasing the welding area of the third welding surface 23.

In some embodiments, when viewed along the first direction Z, the third welding surface 23 is arc-shaped for forming the receiving groove 235. Furthermore, such third welding surface 23 facilitates flow of the solder in the third welding surface 23 and facilitates the contact of the solder with the first welding surface 21 and the second welding surface 22.

In other embodiments, when viewed along the first direction Z, the groove wall 131 and the third welding surface 23 are substantially U-shaped, or the groove wall 131 and the third welding surface 23 are substantially V-shaped.

In some embodiments, when viewed along the first direction Z, a projection of the first welding surface 21 and a projection of the second welding surface 22 coincide, so that the first welding surface 21 and the second welding surface 22 are subjected to a same force at both ends of the third welding surface 23, thereby improving a stability of the first pad 20.

In other embodiments, when viewed along the first direction Z, the projection of the first welding surface 21 and the projection of the second welding surface 22 are rectangular.

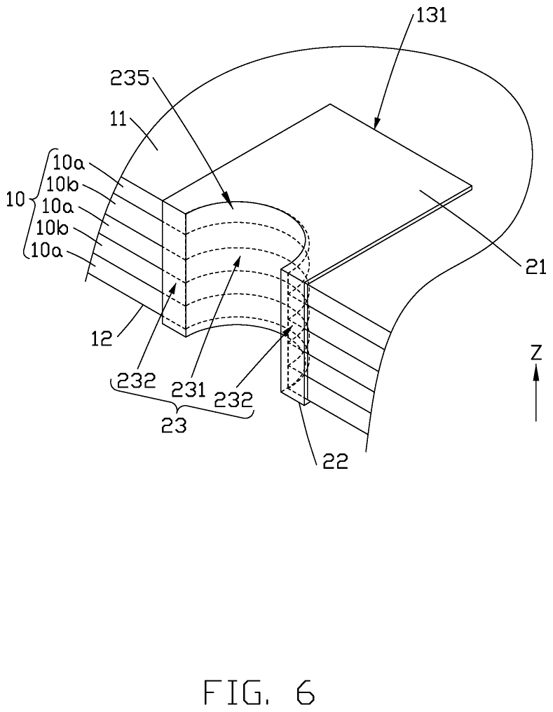

Referring to FIG. 6, in some embodiments, the third welding surface 23 includes a first connecting surface 231 and two second connecting surfaces 232 connected to both sides of the first connecting surface 231. The first connecting surface 231 is arc-shaped to form the receiving groove 235. The second connecting surface 232 connects to the first connecting surface 231 and the side surface 13. The first connecting surface 231 can allow the flowing solder to form thereon, and the second connecting surface 232 can support and connect the solder overflowing from the receiving groove 235, thereby further increasing the welding area of the first pad 20 and facilitating the connection of the first pad 20 with the terminal 91, and improving the reliability of the connection of the circuit board assembly 100 and the external circuit board 90.

In some embodiments, one end of the first connecting surface 231 is connected to the first welding surface 21, and another end of the first connecting surface 231 is connected to the second welding surface 22. One end of the second connecting surface 232 is connected to the first welding surface 21, and another end of the second connecting surface 232 is connected to the second welding surface 22, so as to improve the structural stability of the first pad 20.

Referring to FIG. 6, in some embodiments, the first substrate 10 includes a plurality of conductive layers 10a and at least one insulating layer 10b stacked in the first direction Z. One insulating layer 10b is disposed between two adjacent conductive layers 10a. The conductive layers 10a are made of metal for forming the circuit area. The insulating layer 10b can include a prepreg. The prepreg can include, for example, a resin and a reinforcing material, wherein the reinforcing material can include at least one of glass fibers, a paper-based material, or a composite material. The third welding surface 23 is connected to an exposed portion of the conductive layers 10a from the groove 13a to improve the stability of electrical connection between the first pad 20 and the circuit area of the first substrate 10.

In some embodiments, the first surface 11 is a surface of an outermost conductive layers 10a, and the second surface 12 is a surface of another outermost conductive layer 10a. The first welding surface 21 and the second welding surface 22 are respectively connected to and coplanar with the first surface 11 and the second surface 12.

In some embodiments, the first substrate 10 further includes a solder mask layer (not shown). The solder mask layer is disposed on first surface 11 and the second surface 12a and covers the corresponding circuit area of the conductive layer 10a. At least one opening (not shown) is defined on the solder mask layer, and the first welding surface 21 and the second welding surface 22 are disposed inside the opening, which can reduce a risk of damage to the exposed circuit area.

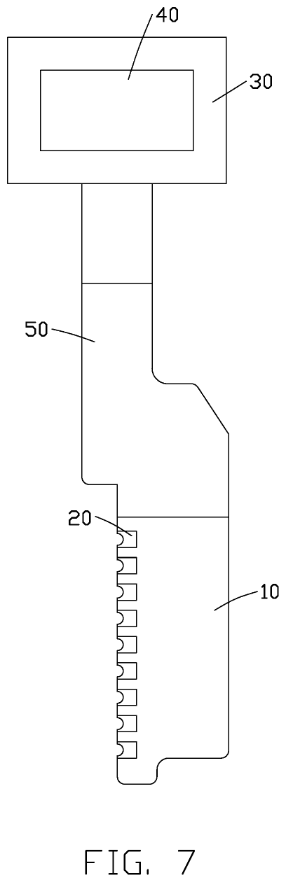

Referring to FIG. 7, in some embodiments, the circuit board assembly 100 further includes a second substrate 30, an electronic component 40, and a flexible circuit board 50. The electronic component 40 connects to the second substrate 30, and the electronic component 40 can be, but is not limited to, a capacitor, inductor, resistor, chip, etc. The flexible circuit board 50 is electrically connected the first substrate 10 to the second substrate 30, so as to facilitate bending the flexible circuit board 50 to adjust the position between the first substrate 10 and the second substrate 30, thereby facilitating the position of the first substrate 10 and the second substrate 30 to adapt to the external circuit board 90.

Referring to FIG. 2, in some embodiments, a positioning groove 13b is defined on the side surface 13, the positioning groove 13b is spaced apart from the groove 13a. The positioning groove 13b can clamp a positioning portion 92 of the external circuit board 90, which is beneficial for stably connecting the first substrate 10 with the positioning portion 92 of the external circuit board 90, thereby improving the reliability of the connection of the circuit board assembly 100.

Referring to FIG. 2, in some embodiments, the terminal device 200 further includes an adhesive layer 60, which is used to bond the first surface 11 and the external circuit board 90, or the second surface 12 and the external circuit board 90, which is beneficial for stably connecting the first substrate 10 to the external circuit board 90, thereby improving the reliability of the connection of the circuit board assembly 100. Specifically, the adhesive layer 60 is disposed on an area of the first surface 11 away from the first welding surface 21, or on an area of the second surface 12 away from the second welding surface 22, to reduce a risk of interference of the adhesive layer 60 with the first pad 20.

A welding area of the first pad 20 can be increased, which can facilitate connection of the first pad 20 to the terminal 91, thereby improving a reliability of the connection of the circuit board assembly 100 and the external circuit board 90.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A circuit board assembly comprising:
a first substrate comprising a first surface, a second surface, and a side surface, the first surface and the second surface being opposite to each other along a first direction, the side surface connecting the first surface to the second surface, at least one groove defined on the side surface and extending through the first surface and the second surface; and
at least one first pad, each of the at least one first pad accommodated in a corresponding groove of the at least one groove and connecting to a groove wall of the corresponding groove, each of the at least one first pad comprising a first welding surface, a second welding surface, and a third welding surface, the first welding surface connecting to the first surface, the second welding surface connecting to the second surface, the third welding surface connecting the first welding surface to the second welding surface.

2. The circuit board assembly of claim 1, wherein the third welding surface comprises a receiving groove.

3. The circuit board assembly of claim 2, wherein the third welding surface further comprises a first connecting surface and two second connecting surfaces each connected to a respective side of the first connecting surface, the first connecting surface is arc-shaped and comprises the receiving groove, and each of the two second connecting surface connects to the respective first connecting surface to the side surface.

4. The circuit board assembly of claim 3, wherein when viewed along the first direction, a projection of the first welding surface and a projection of the second welding surface coincide.

5. The circuit board assembly of claim 1, wherein the first substrate further comprises a plurality of conductive layers and at least one insulating layer, the plurality of conductive layers and the at least one insulating layer are stacked in the first direction, an insulating layer of the at least one insulating layer is disposed between two adjacent of the plurality of conductive layers, and the third welding surface is connected to an exposed portion of the plurality of conductive layers from the groove.

6. The circuit board assembly of claim 1 further comprising a second substrate, an electronic component, and a flexible circuit board, wherein the electronic component is connected to the second substrate, and the flexible circuit board is electrically connected the first substrate to the second substrate.

7. The circuit board assembly of claim 1, wherein a positioning groove is defined on the side surface of the first substrate, and the positioning groove is spaced apart from the at least one groove.

8. The circuit board assembly of claim 1, wherein the at least one first pad is made of copper.

9. A terminal device comprising:
a circuit board assembly comprising:
a first substrate comprising a first surface, a second surface, and a side surface, the first surface and the second surface being opposite to each other along a first direction, the side surface connecting the first surface to the second surface, at least one groove defined on the side surface and extending through the first surface and the second surface; and
at least one first pad, each of the at least one first pad accommodated in a corresponding groove of the at least one groove and connecting to a groove wall of the corresponding groove, each of the at least one first pad comprising a first welding surface, a second welding surface, and a third welding surface, the first welding surface connecting to the first surface, the second welding surface connecting to the second surface, the third welding surface connecting the first welding surface to the second welding surface;
an external circuit board; and
at least one second pad electrically connecting the circuit board assembly to the external circuit board.

10. The terminal device of claim 9, wherein the third welding surface comprises a receiving groove, the at least one second pad is accommodated in the receiving groove and disposed on at least one of the first surface and second surface.

11. The terminal device of claim 10, wherein the third welding surface further comprises a first connecting surface and two second connecting surfaces each connected to a respective side of the first connecting surface, the first connecting surface is arc-shaped and comprises the receiving groove, and each of the two second connecting surface connects to the respective first connecting surface to the side surface.

12. The terminal device of claim 11, wherein when viewed along the first direction, a projection of the first welding surface and a projection of the second welding surface coincide.

13. The terminal device of claim 9, further comprising an adhesive layer, wherein the adhesive layer is between the first surface and the external circuit board or between the second surface and the external circuit board.

14. The terminal device of claim 9, wherein the first substrate further comprises a plurality of conductive layers and at least one insulating layer, the plurality of conductive layers and the at least one insulating layer are stacked in the first direction, each of the at least one insulating layer is disposed between two adjacent of the plurality of conductive layers, and the third welding surface is connected to an exposed portion of the plurality of conductive layers from the groove.

15. The terminal device of claim 9, wherein the circuit board assembly further comprising a second substrate, an electronic component, and a flexible circuit board, the electronic component is connected to the second substrate, and the flexible circuit board is electrically connected the first substrate to the second substrate.

16. The terminal device of claim 9, wherein a positioning groove is defined on the side surface of the first substrate, and the positioning groove is spaced apart from the at least one groove, the external circuit board comprises a positioning portion, the positioning portion is clamped in the positioning groove.

17. The terminal device of claim 9, wherein the at least one first pad is made of copper.
